(19) United States
(12) Patent Application Publication
(10) Pub. No.: US 2017/0358444 A1
(43) Pub. Date: Dec. 14, 2017

(54) Lanthanum Precursors For Deposition Of Lanthanum, Lanthanum Oxide And Lanthanum Nitride Films

(71) Applicant: Applied Materials, Inc., Santa Clara, CA (US)

(72) Inventors: David Thompson, San Jose, CA (US); Jeffrey W. Anthis, San Jose, CA (US)

(21) Appl. No.: 15/621,018

(22) Filed: Jun. 13, 2017

Related U.S. Application Data
(60) Provisional application No. 62/349,628, filed on Jun. 13, 2016.

(51) Int. Cl. H01L 21/02; C23C 16/34; C23C 16/40; C23C 16/18

(52) U.S. Cl. CPC H01L 21/02192; C23C 16/18; C23C 16/34; H01L 21/0228; C23C 16/40

(57) ABSTRACT

Metal coordination complexes comprising a metal atom coordinated to at least one aza-allyl ligand having the structure represented by:

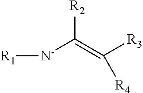

where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens. Methods of depositing a film using the metal coordination complex and a suitable reactant are also described

### CROSS-REFERENCE TO RELATED APPLICATIONS

This application claims priority to U.S. Provisional Application No. 62/349,628, filed Jun. 13, 2016, the entire disclosure of which is hereby incorporated by reference herein.

### TECHNICAL FIELD

The present disclosure relates generally to methods of depositing thin films. In particular, the disclosure relates lanthanum precursors and methods of deposition lanthanum containing films.

### BACKGROUND

Lanthanum can be used in the gate as a high k metal gate oxide material or as a work function tuning material. Precursors for use in the gate should have sufficient stability to remain in-tact over the course of the ampoule life under the delivery conditions. The precursor should also have sufficient vapor pressure under the delivery conditions to deliver a saturated dose in a short period of time. Suitable precursor should also be reactive with the co-reactant to yield the desired LaO, LaN or La film

Therefore, there is a need in the art for lanthanum precursors for the deposition of lanthanum containing films.

### SUMMARY

One or more embodiments of the disclosure are directed to metal coordination complexes comprising a metal atom coordinated to at least one aza-allyl ligand having the structure represented by:

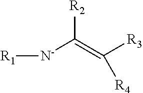

where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

Additional embodiments of the disclosure are directed to metal coordination complexes comprising lanthanum atoms having the general structure:

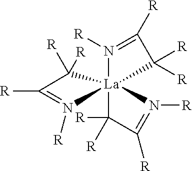

where each R is independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

Further embodiments of the disclosure are directed to processing methods comprising exposing a substrate surface to a metal precursor and a reactant to deposit a film on the substrate surface. The metal precursor comprises a metal coordination complex with a metal atom coordinated to at least one aza-allyl ligand having the structure represented by:

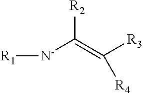

where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure are directed to a new class of metal (e.g., La) precursors that incorporate aza-allyl ligands. Formula (1) shows the general structure of an aza-allyl ligand which can be used with various embodiments of the disclosure. Some embodiments of the disclosure are directed to metal coordination complexes comprising a metal atom coordinated to at least one ligand having the structure represented by Formula (1):

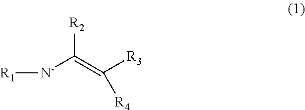

where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

The aza-allyl ligands of some embodiments have a base structure of N—C═C with substituents on each of the base atoms that can be H, branched or unbranched alkyl groups, alkenyl groups, alkynyl groups, cycloalkyl groups having in the range of 1 to 6 carbon atoms, silyl groups and halogens. In some embodiments, one or two of the R groups is an alkyl group with 4 or 5 carbon atoms and the other R groups are hydrogen. In one or more embodiments, one or two of the R groups are trimethylsilyl groups and the other R groups are hydrogen. In some embodiments, one or two R groups are trifluormethyl groups and the other R groups are hydrogen.

Without being bound by any particular theory of operation, it is believed that the ligand is mono-anionic and is able to bond to the metal atom through an η¹-N and η²-CC bonding mode.

In some embodiments, two, three or four ligands bond to each metal atom. The compounds can be homoleptic (all of the ligands are the same) or heteroleptic (different ligands). In one or more embodiments, the lanthanum atom exists in an equilibrium with the η¹-C and η²-CN bonding modes.

The metal can be any suitable metal including any of the lanthanides, yttrium or scandium. In some embodiments, the metal is selected from the group consisting of La, Ce, Pr, Nd, Pm, Sm, Eu, Gd, Tb, Dy, Ho, Er, Tm, Yb, Lu, Y, Sc and combinations thereof. Examples and embodiments may be discussed with regard to the lanthanum atom; however, those skilled in the art will understand that this is merely exemplary and should not be taken as limiting the scope of the disclosure.

Without being bound by any particular theory of operation, it is believed that the bonding of aza-allyl with lanthanides is consistent with Scheme 2.

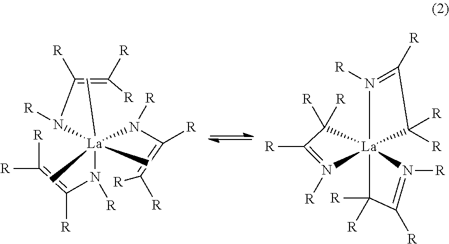

In use as an atomic layer deposition or chemical vapor deposition precursor, a suitable compound may be reacted with the aza-allyl precursor. In a chemical vapor deposition (CVD) process, the aza-allyl precursor and the co-reactant are allowed to mix and react in the gas phase to deposit on the surface of the substrate.

In an atomic layer deposition (ALD) process, the aza-allyl precursor and the co-reactant are flowed separately into the process chamber, or flowed into separate isolated sections of the process chamber to prevent or minimize any gas phase reactions. In the ALD process, the aza-allyl precursor is allowed to chemisorb or react with the substrate surface, or a material on the substrate surface. The co-reactant can then react with the chemisorbed aza-allyl to form the target film. In and ALD reaction, the precursor and co-reactant are sequentially exposed to the substrate surface; meaning that one of the precursor and co-reactant is exposed to the substrate surface (or portion of the substrate surface) at any time.

Suitable co-reactants include, but are not limited to, hydrogen, ammonia, hydrazine, hydrazine derivatives, oxygen, ozone, water, peroxide, combinations and plasmas thereof. In some embodiments, the co-reactant comprises one or more of NH₃, hydrazine, hydrazine derivatives, NO₂, combinations thereof, plasmas thereof and/or nitrogen plasma to deposit an metal nitride film (e.g., LaₓN_{y}). In some embodiments, the co-reactant comprises one or more of O₂, O₃, H₂O₂, water, plasmas therof and/or combinations thereof to deposit a metal oxide film (e.g., LaₓO_{y}). In some embodiments, the co-reactant comprises one or more of H₂, hydrazine, combinations thereof, plasmas thereof, argon plasma, nitrogen plasma, helium plasma, Ar/N₂ plasma, Ar/He plasma, N₂/He plasma and/or Ar/N₂,He plasma to deposit a metal film (e.g., La).

Some embodiments of the disclosure are directed to lanthanum precursors and methods of depositing lanthanum containing films. The lanthanum containing films of some embodiments comprises one or more of lanthanum metal, lanthanum oxide, lanthanum nitride, lanthanum carbide, lanthanum boride, lanthanum oxynitride, lanthanum oxycarbide, lanthanum oxyboride, lanthanum carbonitride, lanthanum borocarbide, lanthanum oxycarbonitride, lanthanum oxyboronitride and/or lanthanum oxyborocarbonitride. Those skilled in the art will understand that the film deposited may have a non-stoichiometric amount of metal, oxygen, nitrogen, carbon and/or boron atoms on an atomic basis. Boron and/or carbon atoms can be incorporated from the metal precursor or the reactant.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A metal coordination complex comprising a metal atom coordinated to at least one aza-allyl ligand having the structure represented by: 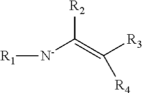
where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

2. The metal coordination complex of claim 1, wherein each or the R groups are independently selected from H and branched or unbranched C1-C6 alkyl groups.

3. The metal coordination complex of claim 1, wherein one or two of the R groups comprises an alkyl group having 4 or 5 carbon atoms.

4. The metal coordination complex of claim 1, wherein one or two of the R groups is a trimethylsilyl group.

5. The metal coordination complex of claim 1, wherein one or two of the R groups comprises a trifluoromethyl group.

6. The metal coordination complex of claim 1, wherein the metal atom is selected from the group consisting of La, Ce, Pr, Nd, Pm, Sm, Eu, Gd, Tb, Dy, Ho, Er, Tm, Yb, Lu, Y, Sc and combinations thereof.

7. The metal coordination complex of claim 6, wherein the metal atom comprises La and there are three aza-allyl ligands.

8. A metal coordination complex comprising lanthanum atoms having the general structure: 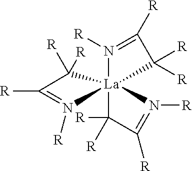
where each R is independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

9. The metal coordination complex of claim 8, wherein each R is selected from the group consisting of H and branched or unbranched C1-C6 alkyl groups.

10. The metal coordination complex of claim 8, wherein the complex is homoleptic.

11. The metal coordination complex of claim 8, wherein the complex is heterleptic.

12. A processing method comprising exposing a substrate surface to a metal precursor and a reactant to deposit a film on the substrate surface, the metal precursor comprising a metal coordination complex with a metal atom coordinated to at least one aza-allyl ligand having the structure represented by: 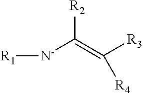
where each R1-R4 are independently selected from the group consisting of H, branched or unbranched C1-C6 alkyl, branched or unbranched C1-C6 alkenyl, branched or unbranched C1-C6 alkynyl, cycloalkyl groups having in the range of 1 to 6 carbon atoms, silyl groups and halogens.

13. The processing method of claim 12, wherein the metal atom is selected from the group consisting of La, Ce, Pr, Nd, Pm, Sm, Eu, Gd, Tb, Dy, Ho, Er, Tm, Yb, Lu, Y, Sc and combinations thereof.

14. The processing method of claim 13, wherein the metal atom comprises La and there are three aza-allyl ligands.

15. The processing method of claim 14, wherein the metal coordination complex is homoleptic.

16. The processing method of claim 14, wherein the metal coordination complex is heteroleptic.

17. The processing method of claim 12, wherein the reactant comprises one or more of NH₃, hydrazine, hydrazine derivatives, NO₂, combinations thereof, plasmas thereof or nitrogen plasma to deposit an metal nitride film.

18. The processing method of claim 12, wherein the reactant comprises one or more of O₂, O₃, H₂O₂, water, plasmas thereof or combinations thereof to deposit a metal oxide film.

19. The processing method of claim 12, wherein the reactant In some embodiments, the co-reactant comprises one or more of H₂, hydrazine, combinations thereof, plasmas thereof, argon plasma, nitrogen plasma, helium plasma, Ar/N₂ plasma, Ar/He plasma, N₂/He plasma or Ar/N₂/He plasma to deposit a metal film.

20. The processing method of claim 12, wherein the metal precursor and the reactant are exposed to the substrate surface sequentially.
